(19) United States
(12) Patent Application Publication
(10) Pub. No.: US 2020/0294090 A1
(43) Pub. Date: Sep. 17, 2020

(54) BATTERY INFORMATION PROVISION SYSTEM

(71) Applicant: KABUSHIKI KAISHA TOSHIBA, Minato-ku (JP)

(72) Inventors: Tomokazu MORITA, Funabashi (JP); Yumi FUJITA, Chuo (JP); Nobukatsu SUGIYAMA, Kawasaki (JP); Ena ISHII, Yokohama (JP)

(73) Assignee: KABUSHIKI KAISHA TOSHIBA, Minato-ku (JP)

(21) Appl. No.: 16/563,643

(22) Filed: Sep. 6, 2019

(30) Foreign Application Priority Data
Mar. 13, 2019 (JP) 2019-046494

(51) Int. Cl. G06Q 30/02; G01R 31/392; G01R 31/382; G01R 31/367

(52) U.S. Cl. CPC G06Q 30/0255; G01R 31/392; H02J 7/0068; G01R 31/367; G01R 31/382

(57) ABSTRACT

A battery information provision system, which is an embodiment of the present invention, includes: a storage device that stores battery information; a first server configured to extract the battery information from the storage device; and a second server configured to transmit the extracted battery information to a communication device. The battery information is information related to rechargeable batteries or devices including rechargeable batteries, and includes information corresponding to evaluation categories determined according to deterioration states of the rechargeable batteries. The first server extracts battery information corresponding to both a battery or a device designated by the communication device and an evaluation category designated by the communication device.

### CROSS-REFERENCE TO RELATED APPLICATION (S)

This application is based upon and claims the benefit of priority from Japanese Patent Application No. 2019-046494, filed Mar. 13, 2019; the entire contents of which are incorporated herein by reference.

### FIELD

Embodiments described herein relate generally to a battery information provision system.

### BACKGROUND

Mobile communication devices such as smartphones have made outstanding advances in several years past, and therefore cycle of replacing them has been very short. However, the advances of mobile communication devices are gradually peaking out, and there are little differences between latest models and older models. Accordingly, there are increasing situations where the cycles of replacing mobile communication devices are prolonged, and older models are purchased on a secondhand market to save costs.

For batteries for use of mobile communication devices such as smartphones, nonaqueous electrolyte secondary batteries such as lithium-ion batteries are used. Such secondary batteries are known to have a risk of leading to an incident such as emitting smoke or ignition. Such a risk increases with battery deterioration. A degree of battery deterioration increases with years of use. However, since a usage environment also affects battery deterioration, a small number of years of use does not always mean that a battery is not deteriorated. For example, it is known that if a device continues to be used while a battery is being charged, deterioration of the battery is accelerated.

It is therefore conceivable that situations will increase in future where while a mobile communication device itself can be used, an included battery progressively deteriorates, resulting in an incident such as emitting smoke or ignition. Accordingly, it is necessary to have users recognize a deterioration state of a battery.

However, it is conceivable that even after deterioration of a battery is recognized, many users continue to use the battery, considering costs. It sometimes happens that users do not know what to do when the users recognize battery deterioration. Even if a user desires to replace a deteriorated battery or sell his/her mobile communication device, it is expected to takes time and effort for the user to determine a dealer to use. Accordingly, a system is required that provides information for allowing a user who recognizes deterioration of a battery to smoothly replace the battery or a device including the battery.

### BRIEF DESCRIPTION OF THE DRAWINGS

FIG. 1 is a conceptual diagram of an information system according a first embodiment;

FIG. 2 is a diagram illustrating an example of merchandise data recorded in a database;

FIG. 3 is a diagram illustrating another example of the merchandise data recorded in the database;

FIG. 4 is a block diagram illustrating an example of a schematic configuration of a user communication device according to the first embodiment;

FIG. 5 is a diagram illustrating an example of an outputted evaluation category;

FIG. 6 is a general flowchart of processing until the user communication device determines an evaluation category;

FIG. 7 is a general flowchart of processing until the user communication device requests a user front server to provide information;

FIG. 8 is a diagram illustrating an example of information provided from a battery information provision system;

FIG. 9 is a general flowchart of a series of processing related to the provision of the information from the battery information provision system;

FIG. 10 is a conceptual diagram of an information system according to a second embodiment;

FIG. 11 is a diagram illustrating an example of data transmitted from the user communication device to a vendor communication device;

FIG. 12 is a general flowchart of communication between the user communication device and the vendor communication device;

FIG. 13 is a conceptual diagram of an information system according to a third embodiment; and

FIG. 14 is a diagram illustrating an example of a statistical result.

### DETAILED DESCRIPTION

A system that provides information for urging replacement of a battery, or a device including a battery, is provided.

A battery information provision system, which is an embodiment of the present invention, includes: a storage device that stores battery information; a first server configured to extract the battery information from the storage device; and a second server configured to transmit the extracted battery information to a communication device. The battery information is information related to rechargeable batteries or devices including rechargeable batteries, and includes information corresponding to evaluation categories determined according to deterioration states of the rechargeable batteries. The first server extracts battery information corresponding to both a battery or a device designated by the communication device and an evaluation category designated by the communication device.

Below, a description is given of embodiments of the present invention with reference to the drawings. The present invention is not limited to the embodiments.

### First Embodiment

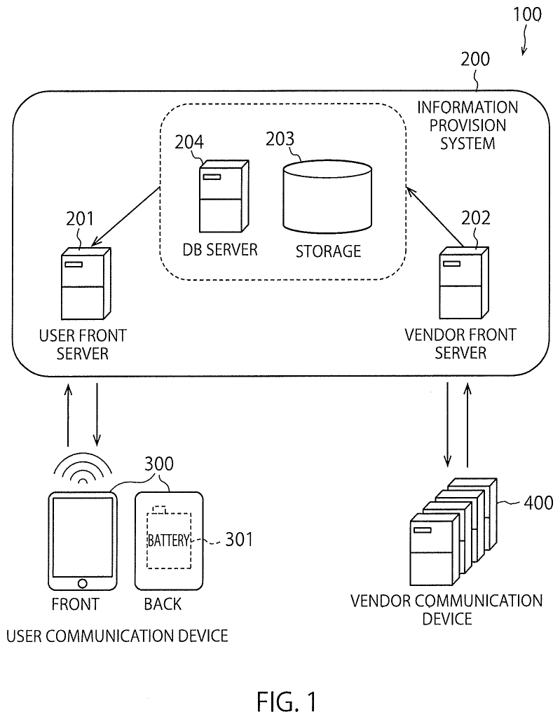

FIG. 1 is a conceptual diagram of an information system according a first embodiment. FIG. 1 illustrates the information system 100 including a battery information provision system 200, a user communication device 300 that is provided with information from the battery information provision system 200, and vendor communication devices 400 that provide base information from which the information provided by the battery information provision system 200 is derived.

The battery information provision system 200 is a system that provides a user who has recognized deterioration of a rechargeable battery with battery information related to the battery or a device including the battery, in order to allow the user to smoothly replace the battery or the device including the battery. For the battery information provision system 200, a web system on the Internet, such as a cloud service, is assumed. The battery information provision system 200 in the first embodiment includes a user front server (second server) 201, a vendor front server (third server) 202, a storage (storage device) 203, and a database server (first server) 204.

The user front server 201 is a server that controls communication with the user communication device 300 (that is, a user). The vendor front server 202 is a server that controls communication with the vendor communication devices 400 (that is, vendors). The storage 203 is a storage device that stores data representing the battery information to be provided to the user. The database server 204 is a server that stores data from the vendor communication devices 400 as a database in the storage 203 and extracts data corresponding to a request from the user communication device 300.

Here, it is assumed that the battery information includes at least information about prices of the battery and the device. That is, it is assumed that the battery and the device are merchandise to be trade. Accordingly, the data representing the battery information will be stated as merchandise data. Accordingly, it can be said that the storage 203 stores the merchandise data including information of merchandise items to be provided to the user.

Incidentally, the servers performing communication externally and the server handling data are separated here in light of actual circumstances such as security, but a coverage of each server, the number of servers, and the like may be changed according to specifications. General components such as a router and a firewall are omitted.

Incidentally, in the present description, a battery refers to a rechargeable battery: for example, a nonaqueous electrolyte secondary battery such as a lithium-ion secondary battery; and an assembled battery using such nonaqueous electrolyte secondary batteries. It is assumed that the term “battery” includes assembled battery, battery module, and cell.

A device including a battery is a device electrically connected to a battery, and may be a device incorporating a built-in battery or may be a device, a battery of which is partially or entirely exposed to an outside. Description will be given, assuming that a device including a battery of which deterioration is recognized by a user is the user communication device 300. However, there can be some cases where such a device is not the user communication device 300. For example, such a device can be a device such as a digital camera connected to the user communication device 300 through a communication cable or the like. Since there are such cases, it is assumed in the present description that a device communicationally connected to the user communication device 300 is comprehensively included in the user communication device 300. In other words, a device communicationally connected to the user communication device 300 is regarded as a part of the user communication device 300.

For the user communication device 300, a communication device is assumed that can measure voltage and current at a time of charging or discharging the battery and can transmit resultant measurement data, or a result of an arithmetic operation of such measurement data, to the user front server 201. The arithmetic operation of the measurement data may be performed by the user communication device 300, or may be performed by the battery information provision system 200. In the present embodiment, description will be given of a case where the arithmetic operation is performed by the user communication device 300, and the result of the arithmetic operation is transmitted to the battery information provision system 200. The result of the arithmetic operation is used as a condition for the battery information provision system 200 to provide information in some cases. The information provided from the battery information provision system 200 to the user communication device 300 varies with the result of the arithmetic operation in some cases. That is, the battery information provision system 200 performs processing, taking the result of the arithmetic operation into consideration.

For the user communication device 300, for example, a communication device that runs by electric power from the included battery, such as a mobile wireless communication device, applies. Examples of the mobile wireless communication device include a mobile telephone (including a smartphone), a laptop computer, an electric vehicle (including a hybrid vehicle using electricity and gasoline), and a drone. Moreover, a communication device that is fixedly installed and does not run by electric power from a battery itself, but manages battery charge, such as a plug-in station, also applies to the user communication device 300. The user communication device 300 may also be a device that does not usually perform communication but can be connected to a communication device, such as an electric bicycle, an electric motorcycle, or an electric forklift. The communication may be wireless communication or may be wired communication. In the following, description will be given, assuming that the user communication device 300 is a smartphone.

The vendor communication devices 400 only need to be communication devices that can provide information to the battery information provision system 200, and are not limited to particular devices.

First of all, a flow of storing data in the storage 203 will be described. First, it is assumed that a vendor assigns a price to a battery or a device including a battery. The price may be a price at which a user purchases from the vendor, or may be a price at which the vendor purchases from a user. Here, from a viewpoint of the vendor, a price at which the vendor sells to a user is stated as a “sales price”, and a price at which the vendor purchases from a user is stated as a “purchase price”. An object to which a price is assigned is stated as a “merchandise item”. Here, for the merchandise item, a battery or a device including a battery is assumed. For the vendor, for example, a manufacturer of the battery or the device including the battery, a secondhand dealer, a recycling trader, a distributor that distributes the battery or the device including the battery to such a secondhand dealer or recycling trader, or the like can be assumed.

It is assumed that the vendor assigns the price by evaluation category, which is defined according to a deterioration state of a battery. The evaluation categories are a plurality of predetermined categories for understanding deterioration states of batteries. For example, the evaluation categories may be distinguished as “not deteriorated”, “slightly deteriorated”, and “deteriorated”. For example, the evaluation categories may be distinguished as “safe”, “caution”, “replacement needed”, and “danger” so that safety can be recognized. Since the safety of a battery is related to a deterioration state thereof, the safety-related evaluation categories can also be said to correspond to deterioration states of batteries.

It is assumable that prices assigned to merchandise items differ according to the evaluation categories. For example, it is conceivable that purchase prices in an evaluation category indicating that deterioration does not progress are higher than purchase prices in an evaluation category indicating that deterioration progresses.

For example, it is conceivable that a vendor engaged in purchase of smartphones sets as follows: the purchase price of a smartphone at 3,000 yen when an included battery belongs to “safe”; the purchase price of a smartphone at 2,000 yen when an included battery belongs to “caution”; the purchase price of a smartphone at 500 yen when an included battery belongs to “replacement needed”; and the purchase price of a smartphone at 10 yen when an included battery belongs to “danger”. Incidentally, if the vendor does not purchase, no purchase price is set.

New merchandise items and secondhand merchandise items may be distinguished by establishing evaluation categories such as “new” and “unused”. For example, it is conceivable that a battery dealer sets the sales price of a battery belonging to “new” (that is, a new battery) at 1,000 yen, sets the sales price of a battery belonging to “safe” (that is, a safe secondhand battery) at 500 yen, and does not sell a battery belonging to “caution”, “replacement needed”, or “danger”. As described above, objects indicated by the evaluation categories also include new undeteriorated merchandise items.

The number of the evaluation categories may be two or more so that a difference between, or differences among, deterioration states can be recognized. The evaluation categories may be distinguished by using points. In such a case, prices may be expressed by a calculation formula with a point as an argument.

Data including a price thus assigned is transmitted to the vendor front server 202 by each vendor communication device 400. For example, a vendor may enter a price into a file in a predetermined format, such as CSV, and the vendor communication device 400 may upload the file to the vendor front server 202. Alternatively, the vendor front server 202 may provide a price entry form generated in an HTML (Hyper Text Markup Language) form or the like to each vendor communication device 400. The price entry form is provided with a merchandise identifier entry field and price entry fields separately provided for the evaluation categories, respectively, so that a price in each evaluation category can be inputted. The filled price entry form is transmitted to the vendor front server 202 by each vendor communication device 400.

Incidentally, a merchandise identifier means an identifier for identifying the same type of merchandise items. Merchandise items having the same merchandise identifier are assumed to be the same type of merchandise items. For example, a model name, a model number, or the like corresponds to the merchandise identifier.

The vendor front server 202 may receive advertisement data representing advertisement information related to an advertisement for at least one of a merchandise item and a vender dealing with the merchandise item from each vendor communication device 400. In case of an advertisement for a merchandise item, it is assumed that the merchandise identifier is included in the advertisement data. For the advertisement information, information about the merchandise item, such as new merchandise item or secondhand merchandise item, can be assumed. A service for a device, such as repair, upgrade, or replacement, can also be assumed. For a vender in such a case, a manufacturer of the device, a repairer of the device, a communication service provider of the device, or the like can be assumed.

The database server 204 receives the merchandise data and the advertisement data via the vendor front server 202 and stores the merchandise data and the advertisement data in the storage 203 as a database. The database server 204 may edit the merchandise data and the advertisement data. For example, if an identifier of a source vendor is not included in the merchandise data or the advertisement data, the identifier of the vendor is added to the merchandise data and the advertisement data on the basis of a source notified from the vendor front server 202 so that the vendor can also be identified. Moreover, for example, if data indicating a general evaluation assigned when a merchandise item is new is registered in the database, it is conceivable that the general evaluation is added to the merchandise data by merging such data and the merchandise data. It is assumable that the general evaluation is represented by, for example, a figure, an alphabet, the number of stars, or the like.

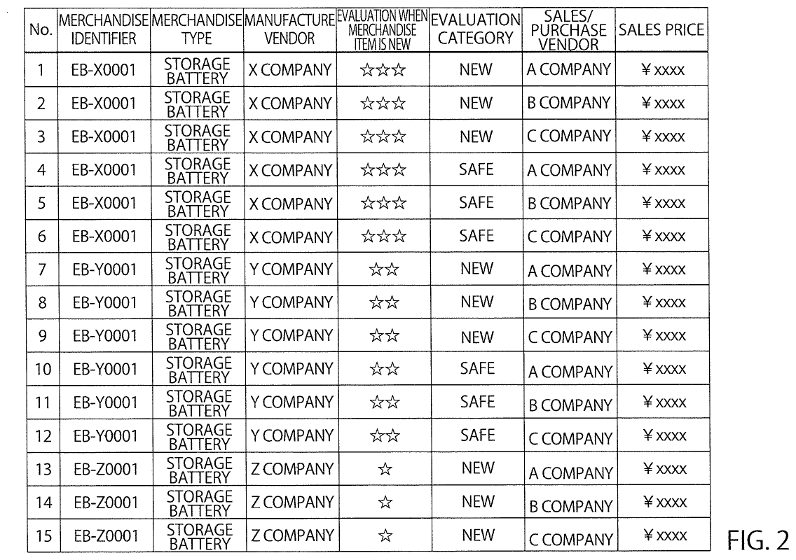

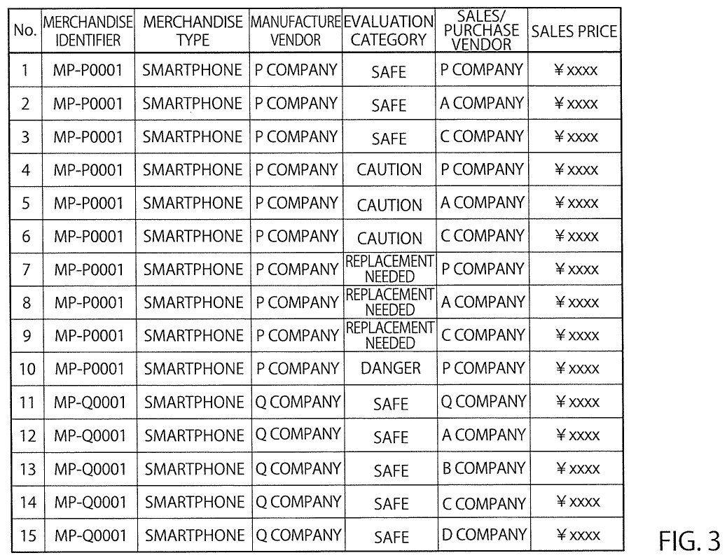

FIG. 2 is a diagram illustrating an example of the merchandise data recorded in the database. FIG. 2 illustrates sales prices of batteries. FIG. 3 is a diagram illustrating another example of the merchandise data recorded in the database. FIG. 3 illustrates purchase prices of smartphones. As illustrated, for each record of the merchandise data, a merchandise identifier, an evaluation category, a pricing vender, a price, and the like are recorded. The prices are assigned on a per evaluation category basis. Accordingly, the merchandise data, that is, the battery information includes information corresponding to each evaluation category. Such merchandise data is stored in the battery information provision system 200.

Incidentally, it is assumed in the above description that the information is provided from each vendor, but it is also conceivable, as in the case of the data indicating the general evaluation, that an administrator of the battery information provision system 200 collects information and registers collected data in the database.

Moreover, it is assumed that other data used in each processing is registered in the database. For example, if the battery information provision system 200 provides information about replaceable batteries, the battery information provision system 200 may provide not only information about the same type of batteries as a battery informed by the user communication device 300 but also information about batteries compatible with the user communication device 300. Accordingly, data representing the information indicating the batteries compatible with the user communication device 300 may also be registered.

Next, operation of the user communication device 300 will be described. As described above, in the present embodiment, the user communication device 300 measures voltage and current at the time of charging the battery and performs the arithmetic operation of the measurement data. More specifically, a parameter or parameters indicating a deterioration state of the battery is calculated, whereby the deterioration state of the battery is estimated. Thus, the deterioration state of the battery is diagnosed. On the basis of the estimated deterioration state, it is determined which one of the evaluation categories the battery belongs to. The user communication device 300 transmits merchandise identifiers of the battery and itself and the determined evaluation category to the user front server 201. Thereby, the user communication device 300 receives corresponding merchandise data. Incidentally, the merchandise identifiers of both the battery and the user communication device 300 are transmitted here, but any one of the merchandise identifiers may be transmitted.

It is assumed that the estimation of the deterioration state of the battery and the determination of the evaluation category are performed by software (a program) installed in the user communication device 300. For a method of estimating the deterioration state of the battery, it is assumed that charge curve analysis (CCA) is performed. In smartphones and the like, a command to check a battery state is prepared in an operating system (OS). However, with the command, it can only be determined whether a battery is normally operating or broken down, and a deterioration state cannot be recognized.

In the charge curve analysis, an internal state and the like of a battery can be estimated, on the basis of the measurement data at the time of charging or discharging the battery. Therefore, a deterioration state of the battery can be estimated while the battery is being used. Thus, work of setting the battery in an inspection apparatus and the like is eliminated, and a burden on the user can be lessened. Incidentally, in the charge curve analysis, a state can be estimated on the basis of any of the measurement data at the time of charge and the measurement data at the time of discharge. Accordingly, in the description of the charge curve analysis, “charge (charging)” can be read for “discharge (discharging)”.

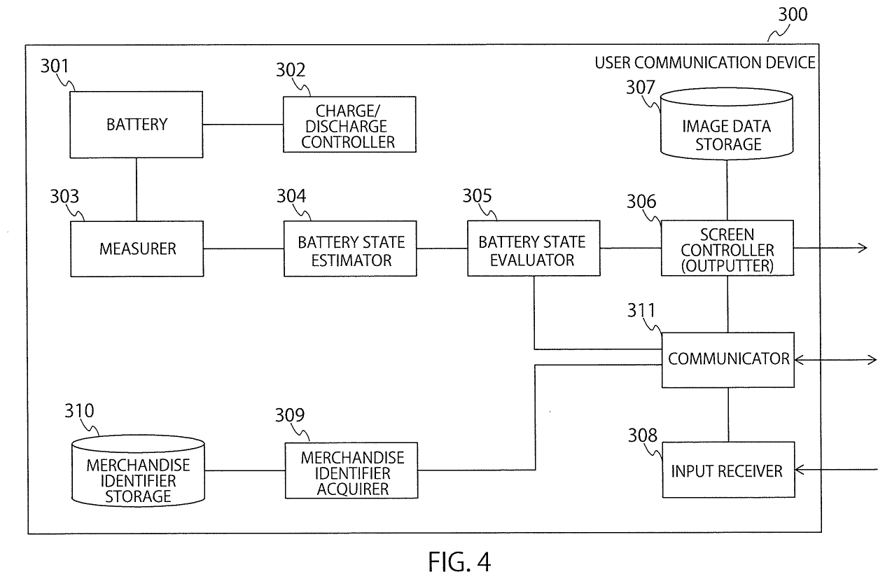

FIG. 4 is a block diagram illustrating an example of a schematic configuration of the user communication device 300 according to the first embodiment. The user communication device 300 in FIG. 4 includes a battery 301, a charge/discharge controller 302, a measurer 303, a battery state estimator 304, a battery state evaluator 305, a screen controller (outputter) 306, an image data storage 307, an input receiver 308, a merchandise identifier acquirer 309, a merchandise identifier storage 310, and a communicator 311.

The components illustrated in FIG. 4 are components that are deemed required to transmit the merchandise identifiers and the evaluation category to the user front server 201. Other components, for example, a component that performs packet generation processing and the like are the same as those of a general communication device and therefore omitted. The components and processing performed by the components can be changed according to specifications and the like. In light of user convenience and security, it is assumed here that a determined evaluation category is displayed and, with permission of the user for communication, transmitted to the user front server 201.

The charge/discharge controller 302 instructs the battery 301 to charge or discharge. Charge or discharge may be performed regularly, or may be performed when an instruction is received from an outside of the user communication device 300 via the input receiver 308, the communicator 311, or the like. Charge or discharge may be performed by using a general method, for example, constant current-constant voltage charge or the like.

The measurer 303 measures voltage and current at the time of charge or discharge and generates the measurement data. The measurement data includes at least a voltage between a positive electrode terminal and a negative electrode terminal of each cell and a current flowing in each cell. In addition, the measurement data may also include others such as a temperature of each cell. Incidentally, the charge or discharge of the battery 301 can be performed not according to an instruction from the charge/discharge controller 302 in some cases. For example, the battery 301 is discharged while the user communication device 300 is being used, and the measurement data may be generated at such a time.

The battery state estimator 304 estimates a current deterioration state of the battery 301 through the charge curve analysis. The battery state estimator 304 can also be said to be a battery diagnoser. The charge curve analysis is to calculate internal state parameters of each cell and battery characteristics, on the basis of the measurement data. More specifically, the internal state parameters are estimated on the basis of the measurement data. The battery characteristics are estimated on the basis of the estimated internal state parameters. Parameters used for the deterioration states may be predetermined, and the parameters may be calculated through the charge curve analysis.

The internal state parameters are parameters indicating a state of a cell. It is assumed that the internal state parameters include positive electrode capacity (positive electrode mass), negative electrode capacity (negative electrode mass), SOC deviation, and internal resistance. The SOC deviation means a difference between an initial charge amount of the positive electrode and an initial charge amount of the negative electrode.

The battery characteristics can be calculated from the internal state parameters, and indicate characteristics such as the voltage of a battery. The battery characteristics include battery capacity, open circuit voltage (OCV), an OCV curve, and the like. The internal resistance may be also included in the battery characteristics. The OCV curve means a graph (function) indicating a relationship between a certain indicator related to the battery and open circuit voltage. The battery capacity is an overlapping range between a range of the positive electrode capacity and a range of the negative electrode capacity.

Details of the charge curve analysis is publicly known, as disclosed in Japanese Patent Laid-Open No. 2017-166874 and others. The calculation of the internal state parameters and the battery characteristics based on the charge curve analysis may be performed in the same manner as in the publicly known schemes.

The battery state evaluator 305 determines which one of the predetermined evaluation categories the current deterioration state of the battery 301 estimated by the battery state estimator 304 belongs to. For example, a threshold value is predetermined for a boundary of each evaluation category, and an applicable evaluation category is determined by comparing a parameter used for the deterioration states with the threshold values.

The screen controller (outputter) 306 outputs the determined evaluation category. For example, it is conceivable that an image including the determined evaluation category is displayed on a screen of the smartphone. It is assumed that data for the displayed image is stored in the image data storage 307 when the software is installed, or the like.

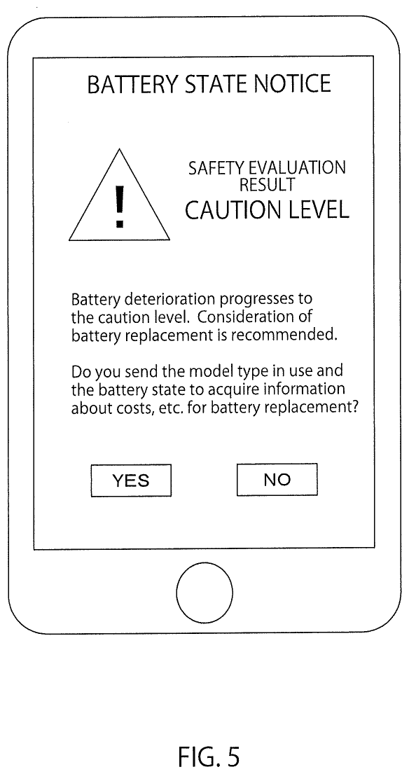

FIG. 5 is a diagram illustrating an example of the outputted evaluation category. FIG. 5 illustrates a case where the evaluation category is “caution”. Using such an image, it is possible to urge the user to replace the battery 301, renew the user communication device 300, or the like. To display the image, an image display software function of the smartphone or the like may be used.

It is assumed that an image for asking permission to transmit the data to the user front server 201 is displayed, as illustrated in FIG. 5. When an image indicating “YES” in FIG. 5 is touched, the input receiver 308 detects the touch and, on the basis of a location of the touch and the indicated image, determines that the image indicating “YES” is touched. Then, transmission-related processing is performed.

The merchandise identifier acquirer 309 acquires the merchandise identifier of the battery 301 or the user communication device 300 from the merchandise identifier storage 310 in which the merchandise identifiers are stored.

In a smartphone or the like, information on model numbers and the like of the smartphone itself and a battery are stored as setting information in general, and a command to read out such information is prepared in the operating system. Moreover, each communication device is assigned an international mobile equipment identifier (IMEI). A maker, a model number, and the like of each communication device can also be identified by referring to the IMEI.

The communicator 311 performs communication with the user front server 201. When permission for transmission is acknowledged by the input receiver 308, the communicator 311 transmits a request to the battery information provision system 200 for provision of information, along with the extracted identifier and the determined evaluation category, to the user front server 201. Thus, the battery information provision system 200 can acquire the information required to provide information.

Incidentally, the communicator 311 may transmit other related data (related data) to the user front server 201. For example, an identifier for recognizing a content of the request may be transmitted, such as “information about a replaceable battery is needed”, “a replaceable battery may be either a new one or a secondhand one”, or “information about purchase of the user communication device 300 is needed”. For example, identifiers for contents of requests may be registered as settings of the installed software, and one of the settings may be transmitted along with the merchandise identifier. Thus, the battery information provision system 200 may acquire the information required to provide information.

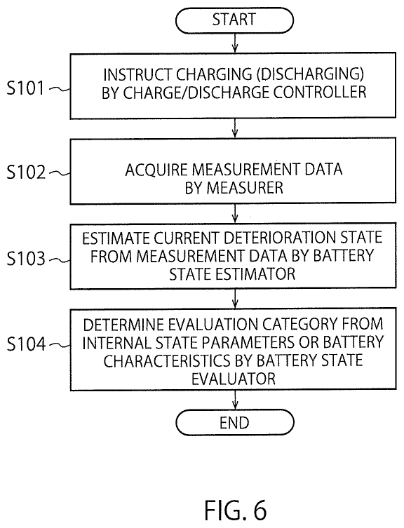

Next, a flow of processing until an evaluation category is determined will be described. FIG. 6 is a general flowchart of the processing until the user communication device 300 determines an evaluation category. Incidentally, the flowchart is an example, and order of processing steps and the like are not limited as long as a required processing result can be obtained. A processing result of each processing step may be stored sequentially in a memory, a storage, or the like of the user communication device 300, and each component may acquire the processing results by referring to the processing results. The same applies to other flowcharts hereinafter.

The charge/discharge controller 302 instructs the battery to charge under a predetermined condition (S101). The measurer 303 acquires the measurement data indicating a current and a voltage at the time of the charge (S102). The battery state estimator 304 calculates the internal state parameters of the battery from the measurement data. If the battery characteristics are to be calculated, the battery state estimator 304 further calculates the battery characteristics on the basis of the internal state parameters. Thus, a current deterioration state is estimated (S103). The battery state evaluator 305 determines an evaluation category for the battery 301 from the internal state parameters or the battery characteristics (S104).

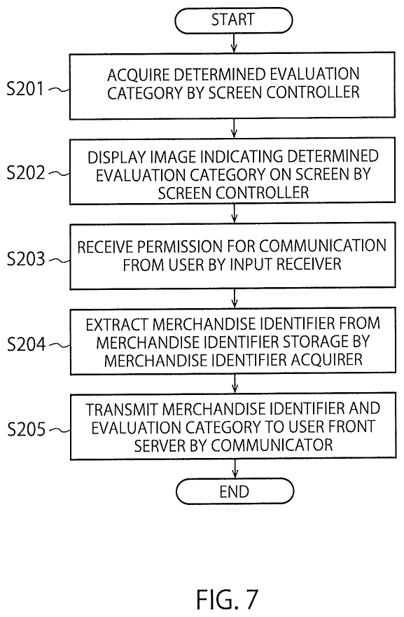

FIG. 7 is a general flowchart of processing until the user communication device 300 requests the user front server 201 to provide information. The screen controller 306 acquires the determined evaluation category (S201). The processing may be performed when software for checking a deterioration state of the battery get activated, or may be performed regularly while the software is in an activated state. The screen controller 306 generates an image indicating the determined evaluation category and displays the image on the screen (S202). The input receiver 308 receives permission for communication from the user (S203). The merchandise identifier acquirer 309 extracts the merchandise identifier from the merchandise identifier storage 310 (S204). The communicator 311 transmits the merchandise identifier and the evaluation category to the user front server 201 (S205). Incidentally, the merchandise identifier may be acquired before the permission for transmission is acquired, similarly to the determination of the evaluation category.

Next, operation of the battery information provision system 200 that has received the request for provision of information will be described. The user front server 201 forwards the merchandise identifier and the evaluation category received from the user communication device 300 to the database server 204.

The database server 204 determines a designated merchandise item on the basis of the merchandise identifier from the user communication device 300. The battery or the device represented by the merchandise identifier may be set as the designated merchandise item. Alternatively, if the merchandise identifier represents the device, a battery that is compatible with the device represented by the merchandise identifier may be set as the designated merchandise item. It may be determined, depending on a type of information to be provided, what is set as the designated merchandise item.

The type of information to be provided may be determined from the identifier for the content of the request transmitted from the communicator 311, or may be determined from settings in the database server 204. Alternatively, all information may be transmitted without performing the determination.

The database server 204 extracts merchandise data related to the designated merchandise item and the evaluation category for the designated merchandise item from the storage 203. For example, if information about purchase of the user communication device 300 is requested, the designated merchandise item is the model type of the user communication device 300, and the evaluation category for the designated merchandise item is the evaluation category for the battery 301 of the user communication device 300. For example, if information about a replaceable battery is requested, the designated merchandise item is the type of the battery 301 or a battery compatible with the user communication device 300, and the evaluation category for the designated merchandise item is an allowable evaluation category or allowable evaluation categories for the designated merchandise item, such as “new”, “safe”, and the like. Accordingly, it can be said that the database server 204 extracts battery information corresponding to both the merchandise item designated by the user communication device 300 and the evaluation category designated by the user communication device 300.

The database server 204 extracts advertisement data corresponding to the selected merchandise data, by using a vendor or a merchandise item indicated in a record of the selected merchandise data as a key. Incidentally, the advertisement data may be extracted on the basis of the related data transmitted from the user communication device 300.

The database server 204 may extract all applicable merchandise data and advertisement data. However, since a data volume becomes enormous, data to be extracted may be limited on the basis of a predetermined condition. The condition may be determined as appropriate according to specifications of the battery information provision system 200. Conceivable examples include order of prices, order of general evaluations, and the like.

The database server 204 may register data indicating priority order of vendors in the storage beforehand, and may preferentially extract the merchandise data and the advertisement data related to a vender assigned a higher priority. It is conceivable that the priority order is determined according to fees paid from the vendors to the battery information provision system 200.

The database server 204 may record the number of extractions of the advertisement data, or the user front server 201 may record the number of transmissions of the advertisement data to the user communication device 300, and the vendor front server 202 may transmit the number of extractions or transmissions of the advertisement data to a contact point of a vendor associated with an advertisement included in the advertisement data. The number of extractions or transmissions can also be used when it has been agreed that the vendor pays a fee depending on the number of deliveries of the advertisement to the administrator of the battery information provision system 200.

The extracted merchandise data and the extracted advertisement data are transmitted to the user communication device 300 via the user front server 201, and the screen controller 306 of the user communication device 300 displays the data. For example, it is conceivable that the user front server 201 forwards an HTML, a CSS (Cascading Style Sheets), an image, or the like for displaying the merchandise data and the advertisement data, and the screen controller 306 renders the HTML, the CSS, the image, or the like and displays the data on a web browser. Alternatively, it is conceivable that the merchandise data and the advertisement data are transmitted, and the screen controller 306 displays the data on an application.

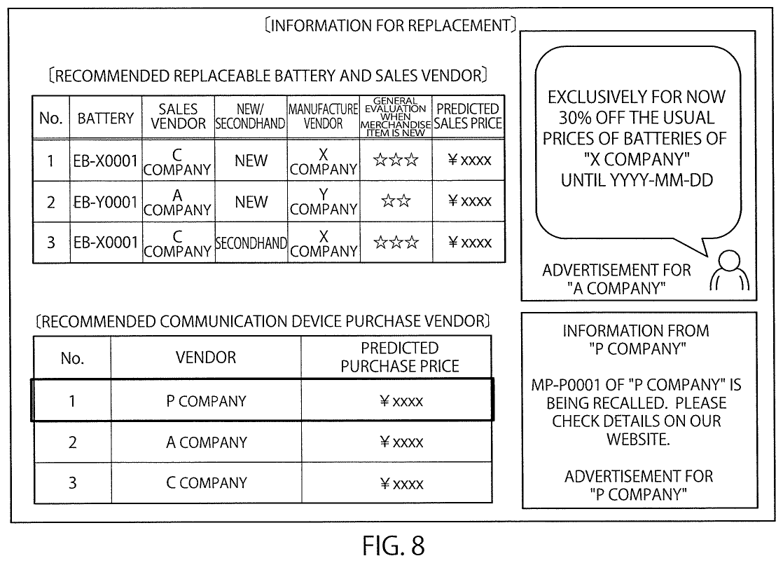

FIG. 8 is a diagram illustrating an example of the information provided from the battery information provision system 200. It is assumable that an image in FIG. 8 is displayed on the screen of the user communication device 300. The image includes a table indicating replaceable batteries and the like, a table indicating vendors that purchase the user communication device 300 and the like, and advertisements.

The table indicating replaceable batteries and the like indicates sales prices of new and secondhand merchandise items of EB-X0001, which represents the battery included in the user communication device 300. An EB-Y0001 battery compatible with MP-P0001, which is the model type of the user communication device 300, is also indicated. General evaluations for the batteries when the batteries are new are also indicated. By providing information for helping determine a replaceable battery to the user in such a manner, indecision of the user in replacement of the deteriorated battery is reduced.

The table indicating vendors that purchase the user communication device 300 and the like indicates predicted purchase prices. Thus, renewal of the user communication device 300 can also be urged. It is assumable that a vendor determines a purchase price after confirming a deterioration state of a battery. However, the predicted purchase prices indicated in the table are extracted according to the evaluation category for the battery 301 of the user communication device 300 and are therefore proximate to actual purchase prices. Accordingly, it is possible to prevent a situation where an actual purchase price is far lower than a predicted price to make a user feel unsatisfied.

The advertisements are displayed on the right side of FIG. 8. The upper-right advertisement is derived from advertisement data extracted by using a battery sales vendor as a key. The lower-right advertisement is derived from advertisement data extracted by using the merchandise identifier of the user communication device 300, which is the designated merchandise item, as a key. The table indicating replaceable batteries and the like shows that “A company” and “C company” are extracted. It may be determined which one of advertisements of the companies is displayed, depending on the priority order or the like. Alternatively, an advertisement of a vender included in a selected row in the table may be displayed.

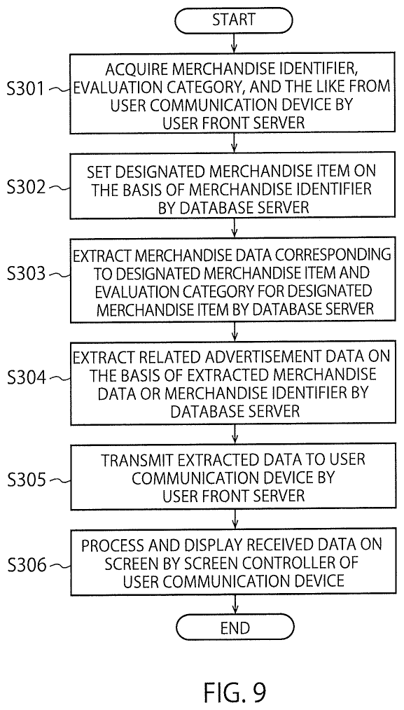

FIG. 9 is a general flowchart of a series of processing related to the provision of the information from the battery information provision system 200. The user front server 201 receives a request for provision of information, along with the merchandise identifier, the evaluation category, and the like, from the user communication device 300 (S301). They are forwarded from the user front server 201 to the database server 204, and the database server 204 sets a designated merchandise item on the basis of the merchandise identifier from the user communication device 300 (S302). As described above, the merchandise identifier may be set as the designated merchandise item, a merchandise item compatible with the merchandise identifier (for example, a battery compatible with the user communication device 300) may be set as the designated merchandise item. The database server 204 extracts some merchandise data from the whole merchandise data, the extracted merchandise data being corresponding to the designated merchandise item and the evaluation category for the designated merchandise item (S303).

The database server 204 extracts related advertisement data (S304). The extraction of the advertisement data may be performed on the basis of the extracted merchandise data, or may be performed on the basis of the merchandise identifier. The user front server 201 transmits the extracted data to the user communication device 300 (S305). The transmitted data is formatted by the screen controller 306 of the user communication device 300 and displayed on the screen (S306). Thus, the information is provided to the user communication device 300, and the user can recognize the information in an image as illustrated in FIG. 8.

As described above, according to the first embodiment, information, such as prices and vendors, useful to a user who considers replacing a battery or a device including a battery is provided to the user. Since such a price varies with a deterioration state of a battery, a deterioration state can be factored in. A purchase price of a communication device, in particular, on which information is provided, is highly reliable because the purchase price is set according to a current deterioration state of a battery, and therefore a large discrepancy from an actual purchase price does not occur.

By notifying an evaluation category indicating a deterioration state of a battery to a user, the user can recognize deterioration of the battery, a hazard associated with the deterioration, and the like, and can be urged to replace the battery. This leads to prevention of an incident such as emitting smoke or ignition attributable to a battery deteriorated to an advanced degree. Moreover, as described above, since a user does not need to input information on a battery and a device, it is also possible to prevent a user who is unwilling to spare time and efforts to make an input from stopping considering replacement.

Further, consequently, sales and purchase of secondhand batteries are promoted, and effects such as mature of the secondhand market, battery reuses, and a reduction in an amount of discarded batteries can also be expected.

### Second Embodiment

It is assumable that the user who has recognized the information provided in the first embodiment contacts a vendor and conducts sales and purchase. At such a time, it is conceivable that the user directly contacts the vendor. However, in such a case, the vendor does not recognize exchanges previously made between the user and the battery information provision system 200, and the user needs to provide information to the vendor. That is, a burden is imposed on the user. In the present embodiment, such a burden is eliminated, and a situation where replacement is not accomplished in the end due to such a burden is prevented. Incidentally, description of the same processing as that of the first embodiment will be omitted.

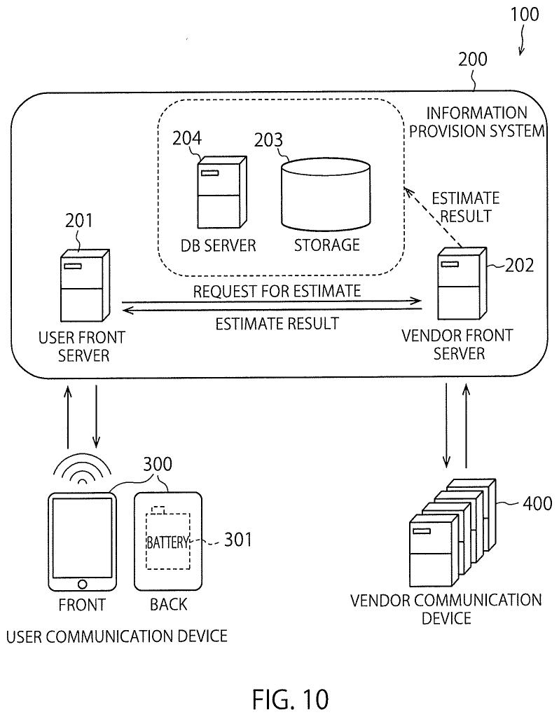

FIG. 10 is a conceptual diagram of an information system 100 according to a second embodiment. In the second embodiment, components of a battery information provision system 200 are the same as those of the first embodiment. However, the user front server 201 and the vendor front server 202 perform communication and mediate information exchanges between the user communication device 300 and each vendor communication device 400.

Incidentally, although the description is given separately from the first embodiment, the battery information provision system 200 in the second embodiment may be the same as the battery information provision system 200 in the first embodiment. If the battery information provision system 200 in the second embodiment is different from the battery information provision system 200 in the first embodiment, the battery information provision system 200 in the second embodiment does not need to include the storage 203 and the database server 204.

It is assumable that the user who has browsed the image of the provided information illustrated in FIG. 8 requests an order with or a formal estimate from a vendor. It is assumed that such a request is transmitted to the battery information provision system 200. For example, if the user communication device 300 is a smartphone, the following is conceivable: When a row within a thick frame in the table illustrated at the lower left of FIG. 8 is selected and double-clicked, the input receiver 308 detects the double-click; and the screen controller 306 recognizes a request meant by the double-click and displays a request form for an order, a formal estimate, or the like on the screen.

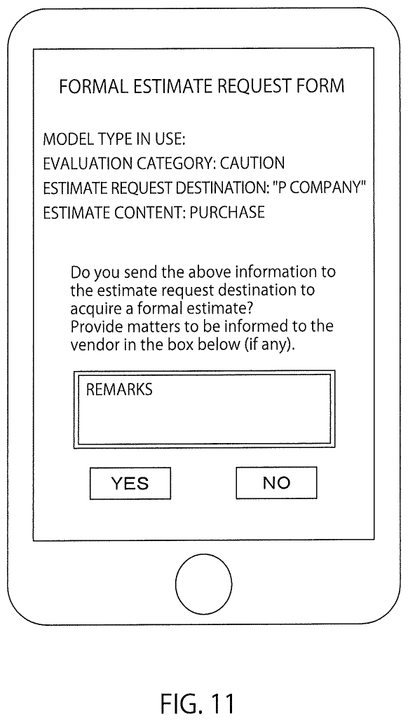

FIG. 11 is a diagram illustrating an example of data transmitted from the user communication device 300 to a vendor communication device 400. A formal estimate request form displayed by the screen controller 306 is illustrated. In the formal estimate request form, the model type of the user communication device 300 and the evaluation category are indicated. Since such information is already acquired in the first embodiment, it is enough to simply display the information. For an estimate request destination and a request content, the information in the row selected in FIG. 8 may be used.

When an image indicating “YES” in the request form is touched, the same processing as that of the first embodiment is performed, and data on the request form is transmitted to the user front server 201, as a request to the vendor. The measurement data and a result of the processing by the battery state estimator 304, that is, a deterioration state may also be included in the message. By transmitting such information, it is expected that an estimate is calculated more accurately.

The user front server 201 forwards the message transmitted from the user communication device 300 to the vendor front server 202. The vendor front server 202 forwards the forwarded message to a vendor communication device 400 designated by the user. The forward-destination vendor communication device 400 may be identified by reading a vendor set as the request destination in the transmitted data. Alternatively, the communicator 311 may allow the user front server 201 to identify a request-destination vendor by generating a packet for identifying the request-destination vendor separately from data packets. Alternatively, the vendor front server 202 may select a vendor to which the message is transmitted. For example, it is conceivable that there is no vendor desired by the user, and selection of a vendor is entrusted. In such a case, the vendor front server 202 may select a vendor to which the message is transmitted. A vender assigned a higher priority may be selected, as in the case of the extraction. Thus, the vendor front server 202 selects one or more vendors from a plurality of vendors and transmits the message to a contact point of each selected vendor.

Incidentally, the transmission from the vendor front server 202 to the vendor communication device 400 may be headed to software running on the vendor communication device 400 or an e-mail address associated with the vendor communication device 400. Accordingly, the message may be a file or may be an e-mail. It is assumed that the vendor front server 202 has recognized a contact point of the vendor communication device 400, such as an IP address, a URL address, or an e-mail address. Any one of such contact points may be registered with the vendor front server 202 as the contact point of the vendor communication device 400 when the vendor communication device 400 accesses the vendor front server 202, as described in the first embodiment.

The vendor that has received the request form transmits to the vendor front server 202 a response to the request form by using the vendor communication device 400. The vendor front server 202 forwards the response to the user front server 201. The user front server 201 records transmissions from the user communication device 300 so that the user front server 201 can identify which transmission the forwarded response is returned to. For example, an identifier for identifying the request form is set, and the user front server 201 records the identifier along with the user communication device 300 that has transmitted the request form. It is also conceivable that for the response from the vendor communication device 400, a packet or the like for identifying the request form is established separately from data and the like. Thus, the user front server 201 can identify a forward destination of the response.

Incidentally, the transmission from the user front server 201 to the user communication device 300 may be headed to the software running on the user communication device 300, or to an e-mail address or the like associated with the user communication device 300. Accordingly, the response to the message may be a file or may be an e-mail. It is assumed that the user front server 201 has recognized a contact point of the user communication device 300, such as an IP address, a port number, or an e-mail address. Any one of such contact points may be registered with the user front server 201 when the user communication device 300 accesses the user front server 201.

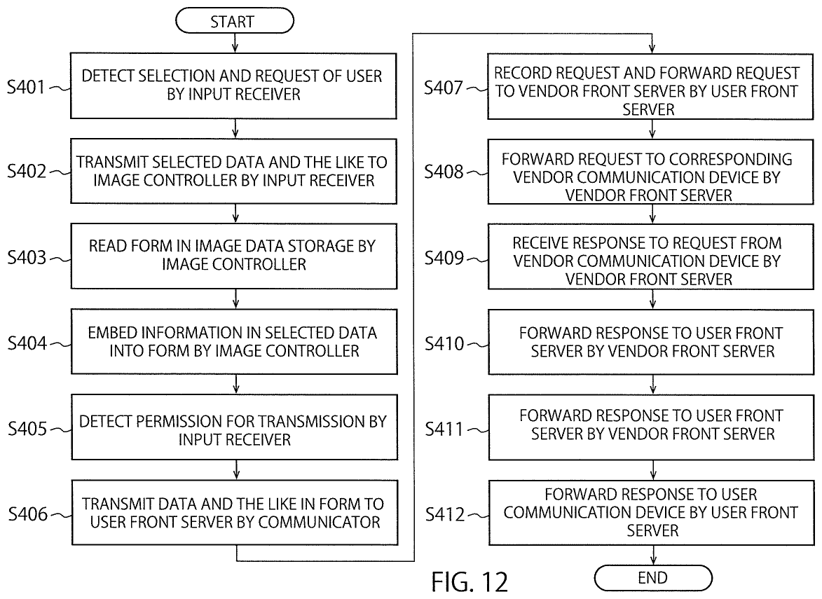

FIG. 12 is a general flowchart of communication between the user communication device 300 and the vendor communication device 400. The input receiver 308 detects a selection and a request of the user (S401) and transmits the selected data and the like to an image controller (S402). The image controller reads a request form stored in the image data storage 307 (S403). The image controller embeds information in the selected data into item fields in the request form and then displays the resultant request form on the screen (S404).

The user who has confirmed the request form performs an operation to permit transmission, and the input receiver 308 detects the operation (S405). Thus, the communicator 311 transmits the data and the like in the form to the user front server 201, as a request to the vendor (S406).

The user front server 201 records the request and forwards the request to the vendor front server 202 (S407). The vendor front server 202 confirms the vendor communication device 400 that is the forward destination of the request and forwards the request (S408).

Since the vendor creates a response to the request and transmits the response by using the vendor communication device 400, the vendor front server 202 receives the response to the request from the vendor communication device 400 (S409). The vendor front server 202 forwards the response to the user front server 201 (S410). The user front server 201 identifies the user communication device 300 that is the forward destination of the response from the record of the request (S411) and forwards the response to the identified user communication device 300 (S412). In such a manner, mediation of the communication is performed.

If the battery information provision system 200 does not perform mediation, a burden on the user is enormous. More specifically, the user needs to search for a website of P company on a search site by using a web browser, access the website of P company, and input the above-described information on the website of P company for oneself. Further, the user also needs to input personal information such as a contact point again. Since the user can discretionarily make an input, an inputted evaluation category is less reliable. Accordingly, provision of the mediation by the battery information provision system 200 has superiority.

Incidentally, the vendor front server 202 may record the number of transmissions of a message for each message-destination vendor, and may transmit the recorded number of transmissions to a contact point of each vendor regularly, or when a predetermined condition, such as the number of transmissions exceeding a threshold value, is met. The number of transmissions indicates the number of times a request for an order, an estimate, or the like is delivered from a user to a vendor by using the battery information provision system 200. Accordingly, the number of transmissions can be used when a fee according to the number of requests from users is paid from a vendor to the administrator of the battery information provision system 200.

Incidentally, in the second embodiment, it is also possible to accumulate data related to estimates provided from vendors to users. It is conceivable that merchandise data is generated by using the accumulated data related to estimates. For example, it is conceivable that an average price of the estimates provided during last few weeks is used for a predicted price in the merchandise data. In such a case, since vendors do not need to upload information to the battery information provision system 200, vendor convenience can also be enhanced.

For example, it is prescribed that an estimate from each company be transmitted in the form of a file in a designated format. The vendor front server 202 transmits the estimate not only to the user front server 201 but also to the database server 204. Since the transmitted estimate is in the form of a file in the designated format, the database server 204 can read information such as a merchandise identifier, an evaluation category, and a price from the estimate file. A vendor can also be identified from a source of each file. Thus, the same merchandise data as those illustrated in FIGS. 2 and 3 can be stored. In such a configuration as described above, since the information in the battery information provision system 200 is updated on the basis of estimates provided to users, vendors do not need to upload merchandise data to the battery information provision system 200 again. Accordingly, burdens on the vendors can also be lessened.

As described above, according to the second embodiment, the battery information provision system 200 mediates information exchanges between the user communication device 300 and each vendor communication device 400. Thus, a burden imposed on the user until the battery or the device including the battery is replaced can be lessened, and the replacement can be performed more smoothly.

### Third Embodiment

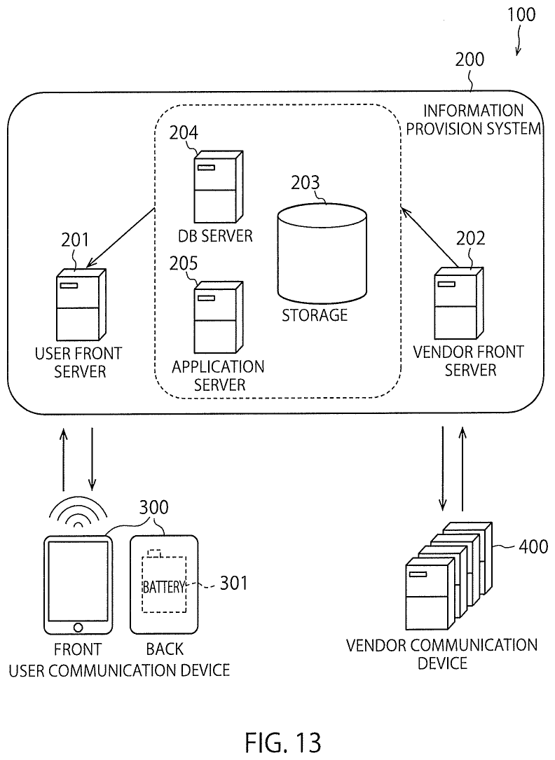

FIG. 13 is a conceptual diagram of an information system 100 according to a third embodiment. In the third embodiment, an application server (fourth and fifth servers) 205 is added as a component of a battery information provision system 200. In the third embodiment, it is assumed that processing other than communication and update of the database is performed by the application server 205. Here, description will be given of a case where the application server 205 estimates a deterioration state of a battery and determines an evaluation category, and of a case where statistical processing is performed on the data in the storage 203.

The case where the application server 205 estimates a deterioration state of a battery and determines an evaluation category will be described. In this case, the application server 205 includes the battery state estimator 304 and the battery state evaluator 305. The measurement data is transmitted from the user communication device 300 to the application server 205 via the user front server 201. As in the first embodiment, the battery state estimator 304 and the battery state evaluator 305 of the application server 205 estimate a deterioration state of the battery and determine an evaluation category. The application server 205 transmits the evaluation category to the user communication device 300 via the user front server 201. Other processing than the processing described above is the same as that of the first embodiment.

If the application server 205 estimates a deterioration state of the battery and determines an evaluation category, a burden on the user communication device 300 can be lessened. Since the measurement data, estimated deteriorations, and the like can be accumulated in the battery information provision system 200, statistical processing, which will be described later, can be performed. For example, vulnerability to deterioration and the like can be examined for each battery type.

Next, an example of the case where the application server 205 performs statistical processing will be described. The application server 205 calculates a representative value of prices of each merchandise item in the merchandise data stored in the storage 203, for each evaluation category. For example, the representative value may be a general value, such as a largest value, a smallest value, a median value, or a mean value. Statistical data representing information related to the calculated representative values is generated as a statistical result. The generated statistical result is stored in the storage 203.

For example, with respect to MP-P0001 smartphones illustrated in FIG. 3, the follows are calculated: an average purchase price for the evaluation category of “safe”; an average purchase price for the evaluation category of “caution”; an average purchase price for the evaluation category of “replacement needed”; and an average purchase price for the evaluation category of “danger” are calculated. Then, it is conceivable that a graph indicating such average values is generated.

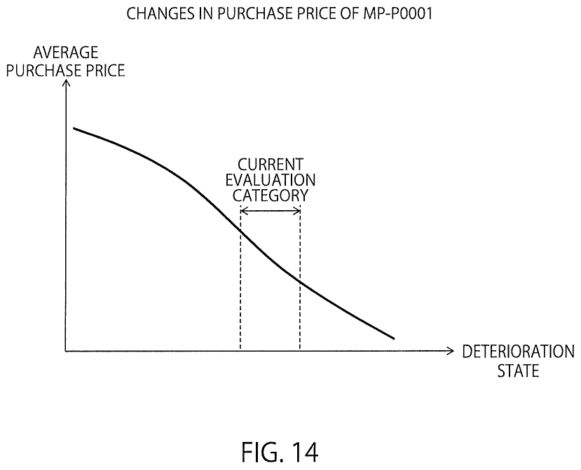

FIG. 14 is a diagram illustrating an example of the statistical result. An approximation graph of the average purchase prices for the evaluation categories for the MP-P0001 smartphone is illustrated. With such a graph, changes in purchase price according to battery deterioration can be seen.

When the database server 204 extracts merchandise data in response to a request from the user communication device 300, the database server 204 also extracts the statistical result from the storage 203 and transmits the statistical result to the user communication device 300. The image controller of the user communication device 300 displays the statistical result as necessary. For example, as illustrated in FIG. 14, the statistical result may be displayed in such a manner that a portion corresponding to an evaluation category can be located. Thus, the user having a look at FIG. 14 can recognize changes in the purchase price of the user communication device 300 and can determine a timing of replacement with taking future decreases in purchase price into consideration. For example, if the purchase price rapidly decreases, it is expected that the user considers replacing the user communication device 300 early.

Incidentally, the single application server may perform the plurality of processings such as the estimation of a deterioration state and the statistical processing, or a plurality of application servers in charge of the processings, respectively, may be provided. For example, the application server may be separated into a battery state diagnosis estimation server (fourth server) that estimates a deterioration state of a battery and a statistics server (fifth server) that performs statistical processing.

As described above, according to the third embodiment, the application server 205 performs the estimation of a deterioration state of a battery, the determination of an evaluation category, the statistical processing, and the like. Thus, it is possible that the battery information provision system 200 lessens a burden on the user communication device 300, generates information useful to the user, and the like.

Incidentally, it is assumed that each processing in the above-described embodiments is implemented by software. More specifically, each processing can be implemented by causing a processor such as a central processing unit (CPU) incorporated in a computer device (hardware), such as a server or a communication device, to execute a software program. Part of the processings may be implemented by using a dedicated circuit instead of the software.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A battery information provision system, comprising:
a storage device that stores battery information related to rechargeable batteries or devices including rechargeable batteries;
a first server configured to extract the battery information from the storage device; and
a second server configured to transmit the extracted battery information to a communication device,
wherein the battery information includes information corresponding to evaluation categories determined according to deterioration states of the rechargeable batteries, and
the first server extracts battery information corresponding to both a battery or a device designated by the communication device and an evaluation category designated by the communication device.

2. The battery information provision system according to claim 1, wherein the designated evaluation category indicates a deterioration state of a battery included in the communication device.

3. The battery information provision system according to claim 1, wherein the storage device further stores advertisement information related to an advertisement for at least one of the rechargeable batteries, the devices including the rechargeable batteries, and vendors dealing with the rechargeable batteries or the devices including the rechargeable batteries,
the first server extracts the advertisement information corresponding to the extracted battery information from the storage device, and
the second server also transmits the extracted advertisement information to the communication device.

4. The battery information provision system according to claim 3, further comprising:
a third server that stores a contact point of a vendor associated with the advertisement,
wherein the second server records the number of transmissions of the advertisement information transmitted to the communication device, and
the third server transmits the recorded number of transmissions to the contact point of the vendor associated with the advertisement included in the advertisement information transmitted to the communication device.

5. The battery information provision system according to claim 1, further comprising:
a third server that store contact points of a plurality of vendors,
wherein when the second server receives from the communication device a message to be transmitted to any of the vendors, the second server forwards the message to the third server, and
the third server selects one or more vendors from the plurality of vendors and transmits the message to the contact point of each of the selected one or more vendors.

6. The battery information provision system according to claim 1, wherein the storage device stores information indicating a battery compatible with the communication device, and
on the basis of the information indicating the compatible battery, the first server extracts information related to the battery compatible with the communication device.

7. The battery information provision system, according to claim 1, further comprising:
the communication device,
wherein the communication device includes an outputter configured to output the information transmitted from the second server.

8. The battery information provision system, according to claim 7, wherein the communication device further includes:
a storage that stores an identifier that makes it possible to identify a same type of an object as the communication device or a battery included in the communication device;
an acquirer configured to acquire the identifier from the storage;
a measurer configured to measure voltage and current at a time of charging or discharging the battery included in the communication device, and to generate measurement data;
a diagnoser configured to diagnose a deterioration state of the battery included in the communication device, on the basis of the measurement data;
an evaluator configured to determine an evaluation category for the battery included in the communication device, on the basis of the diagnosed deterioration state; and
a communicator configured to transmit the identifier and the evaluation category for the battery included in the communication device to the first server via the second server, and
the first server extracts the battery information corresponding to the identifier and the evaluation category for the battery included in the communication device.

9. The battery information provision system according to claim 7, further comprising:
a fourth server configured to diagnose a deterioration state of a battery included in the communication device,
wherein the communication device further includes:
a storage that stores an identifier that makes it possible to identify a same type of an object as the communication device or the battery included in the communication device;
an acquirer configured to acquire the identifier from the storage;
a measurer configured to measure voltage and current at a time of charging the battery included in the communication device, and to generate measurement data; and
a communicator configured to transmit the identifier to the first server and the measurement data to the fourth server via the second server,
the fourth server includes:
a diagnoser configured to diagnose the deterioration state of the battery included in the communication device, on the basis of the measurement data; and
an evaluator configured to determine an evaluation category for the battery included in the communication device, on the basis of the diagnosed deterioration state, and
the first server extracts the battery information corresponding to the identifier and the evaluation category for the battery included in the communication device.

10. The battery information provision system according to claim 1, further comprising:
a fifth server configured to perform statistical processing on the information in the storage device,
wherein the fifth server calculates a representative value of prices of each battery or each device included in the battery information, for each of the evaluation categories,
the storage device further stores the calculated representative values,
the first server extracts information related to the representative values of the battery or the device designated by the communication device, and
the second server transmits the extracted information related to the representative values to the communication device.
